(19) United States
(12) Patent Application Publication
(10) Pub. No.: US 2009/0166011 A1
(43) Pub. Date: Jul. 2, 2009

(54) HEAT DISSIPATION DEVICE HAVING A MOUNTING BRACKET

(75) Inventor: HONG-BO XU, Shenzhen (CN)

Correspondence Address: PCE INDUSTRY, INC.;ATT. Steven Reiss, 458 E. LAMBERT ROAD, FULLERTON, CA, 92835, US

(73) Assignees: HON HAI PRECISION INDUSTRY CO., LTD., Tu-Cheng (TW); HONG FU JIN PRECISION INDUSTRY (ShenZhen) Co., LTD., ShenZhen City (CN)

(21) Appl. No.: 11/964,907

(22) Filed: Dec. 27, 2007

(51) Int. Cl. H01L 23/467

(52) U.S. Cl. 165/121

(57) ABSTRACT

A heat dissipation device includes a heat sink, a plurality of mounting brackets and a fan. The heat sink comprises a central core, a plurality of branches at a circumference of the core and a plurality of fins extending outwardly from the core and branches. Each of the branches has a locking part at a distal end thereof. Each of the mounting brackets comprises a mounting plate engaging with the locking part, a supporting part extending outwardly from a top end of the mounting part and a fixing part extending outwardly from a bottom end of the mounting plate. The fan is supported and secured on the supporting part.

### BACKGROUND OF THE INVENTION

1. Field of the Invention

The present invention relates generally to a heat dissipation device, and particularly to a heat dissipation device having a heat sink and mounting brackets which not only can mount a fan on the heat sink but also can mount the heat sink on a board.

2. Description of Related Art

A computer central processing unit (CPU) mounted on a printed circuit board (PCB) is the core administrator of electrical signals in most contemporary personal computers. Continued development of CPUs has enabled them to perform more and more functions. Heat generated by the CPUs has increased enormously. Such heat can adversely affect the operational stability of the computers. Measures must be taken to efficiently remove the heat from the CPU.

Typically, a heat sink assembly is mounted on the PCB and contacts the CPU to dissipate heat generated by the CPU. The heat sink assembly comprises a heat sink having a heat spreader and a plurality of fins mounted on the heat spreader. A pair of fan covers is mounted on a top of the heat sink at opposite sides of the heat sink by screws extending through the fan covers and threadedly engaging with fins of the heat sink. The fan covers are used for mounting a fan on the heat sink to provide forced airflow to the heat sink. A pair of frames is attached to opposite sides of the heat spreader of the heat sink. A plurality of fasteners extend through the frames and the PCB for mounting the heat sink assembly on the PCB.

However, the process of mounting the fan covers need to form holes in the fan covers and outmost fins of the opposite sides of the heat sink, which is unduly time-consuming and inconvenient. Furthermore, the separate forming of the fan covers and the frames increases the production cost of the heat sink assembly.

Therefore, it is desirable to provide a heat dissipation device having a plurality of mounting bracket for facilitating to firmly fasten a fan to a heat sink and to mount the heat dissipation device on a printed circuit board.

### SUMMARY OF THE INVENTION

The present invention relates to a heat dissipation device includes a heat sink, a plurality of mounting brackets and a fan. The heat sink comprises a central core, a plurality of branches at a circumference of the core and a plurality of fins extending outwardly from the core and branches. Each of the branches has a locking part at distal end thereof. Each of the mounting brackets comprises a mounting plate engaging with the locking part, a supporting part extending outwardly from a top end of the mounting part and a fixing part extending outwardly from a bottom end of the mounting plate. The fan is supported and secured on the supporting part.

Other advantages and novel features will become more apparent from the following detailed description of preferred embodiments when taken in conjunction with the accompanying drawings, in which:

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is an assembled view of a heat dissipation device in accordance with a preferred embodiment of the present invention.

FIG. 2 is an exploded, isometric view of FIG. 1.

FIG. 3 is a partial assembled view of the heat dissipation device in FIG. 2.

FIG. 4 is an enlarged view of a mounting bracket in FIG. 2.

FIG. 5 is an elevation view of the heat dissipation device in FIG. 1, with fixtures in an unlocking state.

FIG. 6 is an elevation view of the heat dissipation device in FIG. 1, with fixtures in a locking state.

### DETAILED DESCRIPTION OF THE INVENTION

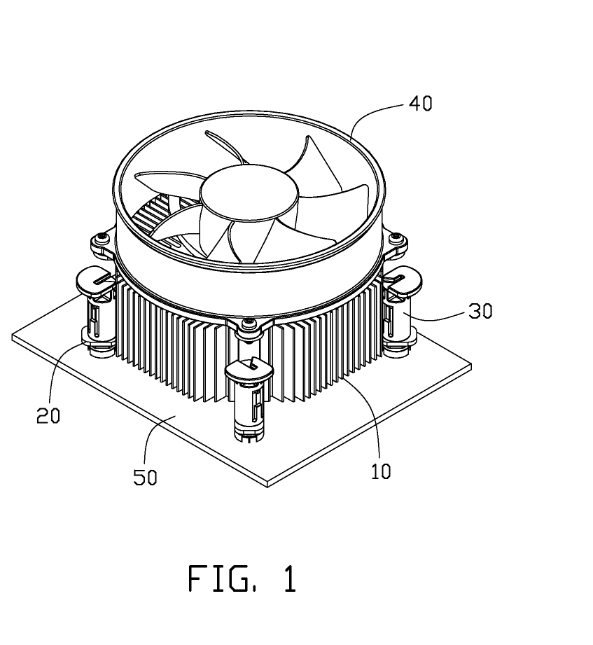

Referring to FIGS. 1 to 3, a heat dissipation device according to a preferred embodiment of the present invention is adapted for removing heat from a heat-generating component 52 mounted on a printed circuit board 50, and comprises a heat sink 10, a plurality of mounting brackets 20, a plurality of fixtures 30 mounting the heat sink 10 onto the printed circuit board 50. The mounting brackets 20 are used for mounting the fan 40 on the heat sink 10 and securing the heat dissipation device on the printed circuit board 50. Four mounting holes 54 surrounding the heat-generating component 52 are defined in the printed circuit board 50 for engaging with the fixtures 30.

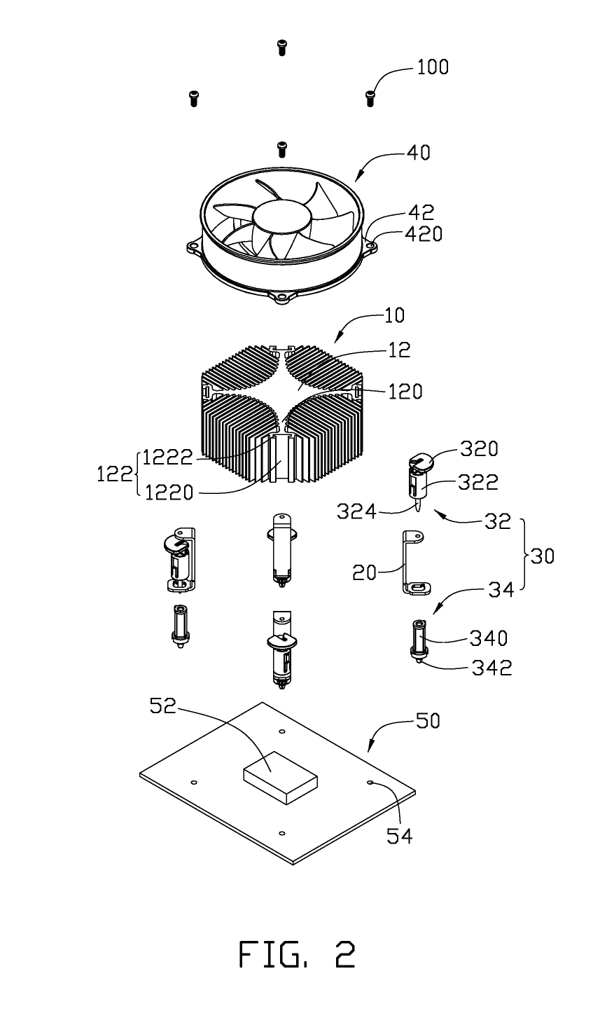

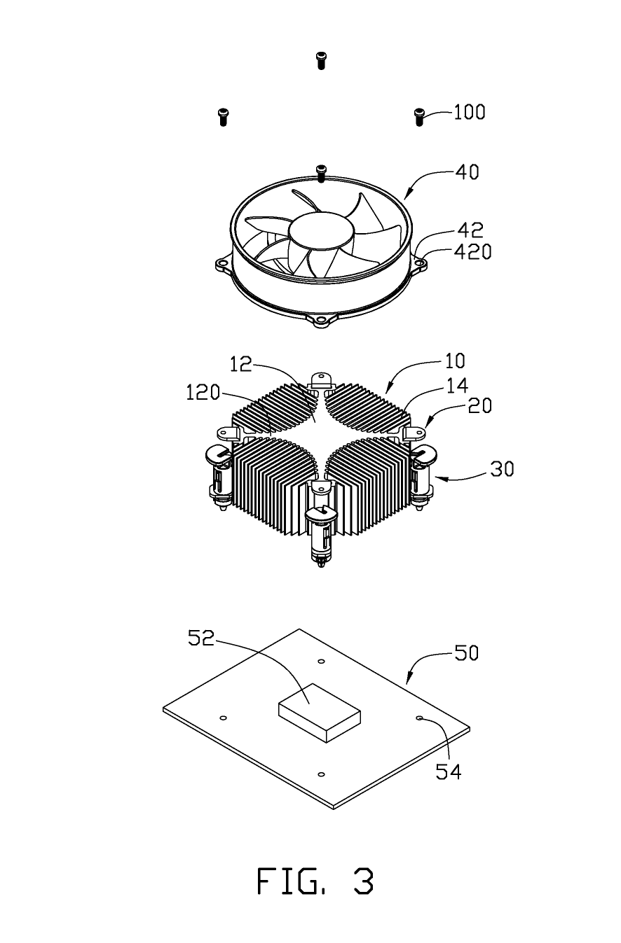

As shown in FIGS. 2 and 3, the heat sink 10 comprises a solid core 12 shaped similar to a prism and four symmetrical branches 120 extending outwardly from four corners of the core 12. The core 12 has a bottom surface in contact with the heat-generating component 52. A locking part 122 is provided at a distal end of each of the branches 120, for engaging with the mounting bracket 20. The locking part 122 has a vertical plate 1220 extending perpendicularly from the distal end of the branch 120. The branch 120 is perpendicular to the corresponding vertical plate 1220 and connected to a middle portion of an inner side of the vertical plate 1220. Two flanges extend perpendicularly and outwardly from two opposite lateral edges of the vertical plate 1220, and are then bent perpendicularly toward each other to define two runners 1222 therein, for locking the mounting bracket 20; thus the locking part 122 provides a guiding channel for the mounting bracket 20 to slide therein. A plurality of fins 14 projects outwardly from a circumference of the core 12 and lateral sides of the branches 120. Four portions of the circumference of the core 12 and four pairs of the facing lateral sides of the branches 120 form four regions. The fins 14 can be thus divided into four groups in the four regions and oriented at four different directions. Two neighboring groups of the fins 14 are oriented perpendicularly to each other. Two adjacent outermost fins 14 of the two neighboring groups of the fins 14 form an included angle of 90 degrees therebetween.

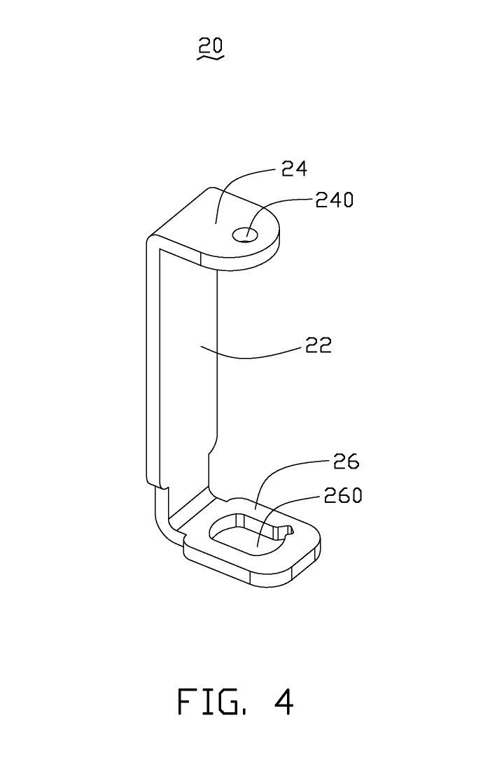

Particularly referring to FIGS. 4, each of the mounting brackets 20 buckled with locking part 122 of the heat sink 10 can be formed by stamping a single piece of metal. Each of the mounting brackets 20 comprises a mounting plate 22 having a height slightly higher than that of the vertical plate 1220 of the heat sink 10, a supporting part 24 extending perpendicularly from a top end of the mounting plate 22 and a fixing part 26 extending perpendicularly from a bottom end of the mounting plate 22. The supporting part 24 and the fixing part 26 are parallel to each other and located to a same lateral side of the mounting plate 22. Each of the supporting parts 24 has a width identical to that of the mounting plate 22 and defines an engaging orifice 240 therein for engaging with screw 100 which extends through the fan 40 to lock the fan 40 thereon. Each of the fixing parts 26 is located below the heat sink 10 and defines a through hole 260 therein for receiving the fixture 30 to mount the heat dissipation device onto the printed circuit board 50. A joint between the mounting plate 22 and the fixing part 26 is recessed inwardly from two opposite lateral sides thereof, therefore has a width less than that of other parts of the mounting plate 22 to enable two opposite lateral sides of the mounting plate 22 to insert into the runners 1222 of the locking part 122 from upper opening of the runners 1222.

Each of the fixtures 30 includes an operating member 32 and a latching member 34. The operating member 32 comprises a handle 320 at top end thereof, a sleeve 322 extending downwardly from the handle 320 and an inserting peg 324 extending from a centre of bottom surface of the handle 320. The latching part 34 comprises a cylinder 340 having a hollow hole therein and a barb 342 at bottom end thereof. The barb 342 therein defines a hollow hole which communicates with the hollow hole of the cylinder 340 and receives the inserting peg 324 therein. To assemble the fixtures 30 to the mounting brackets 20, the operating members 32 are disposed on the fixing parts 26 of the mouthing brackets 20 and the inserting pegs 324 of the operating members 32 are received in the through holes 260 of the fixing parts 26, the cylinders 340 of the latching parts 34 are then inserted into the sleeves 322 through the through holes 260 and the inserting pegs 324 are simultaneously inserted into the through hole of the barbs 342 of the latching parts 34. The fixture 30 is in an unlocking state when a bottom end of the peg 324 is received in the cylinder 340 and has not yet reached the barb 342; the fixture can be turned into a locking state by pressing the handle 320 downwardly to push the bottom end of the peg 324 into the barb 342 and expand the barb 342 dramatically.

The fan 40 comprises a circular frame and a motor received in the frame. The frame has four triangular ears 42 extending outwardly from a circumferential sidewall thereof. A piercing hole 420 is defined in each of the ears 42 and receives one of the screws 100 therein.

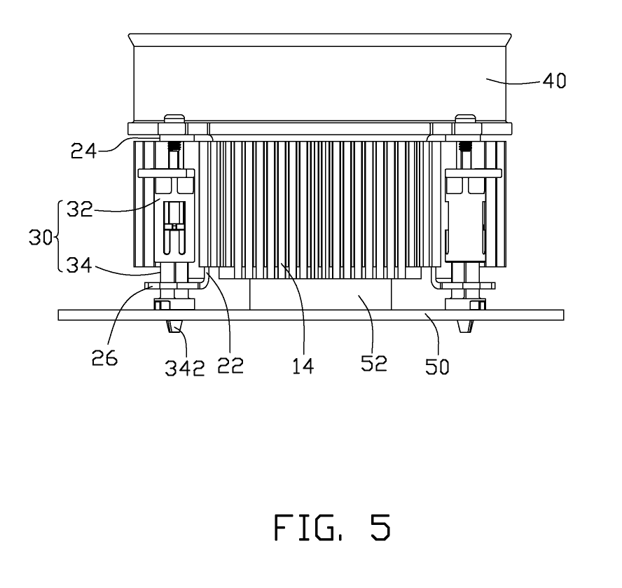

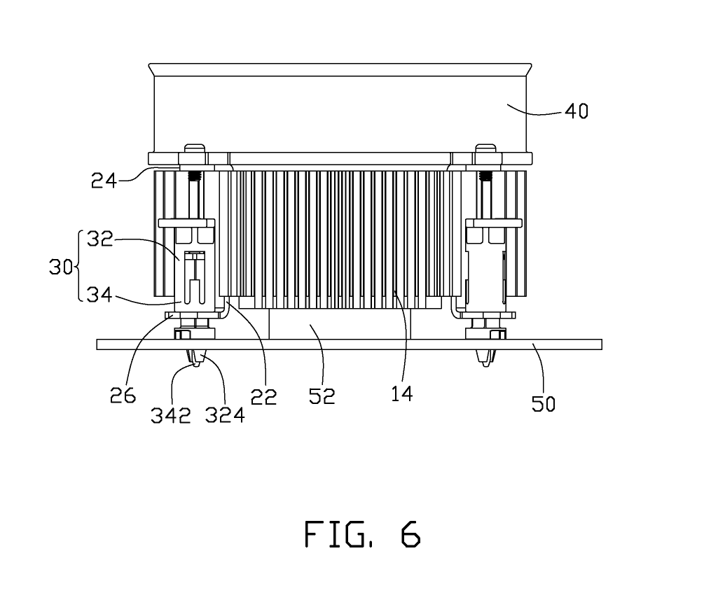

Also referring to FIG. 5 and FIG. 6, in assembly of the heat dissipation device, the mounting brackets 20 equipped with the fixtures 30 are locked in the locking parts 122 of the heat sink 10 by the mounting plates 22 being inserted downwardly into the runners 1222 of the locking parts 122 and the supporting parts 24 of the mounting brackets 20 being blocked on upper ends of the runners 1222. The fan 40 is secured on the top of the heat sink 10 by the screws 100 extending through the piercing holes 420 of the fan 40 and being screwed into the engaging holes 240 of the supporting parts 24 of the mounting brackets 20.

To use of the heat dissipation device, the heat sink 10 is placed on the heat-generating component 52 and the barbs 342 of the fixtures 30 in the unlocking state are inserted into the corresponding mounting holes 54 of the printed circuit board 50. The fixtures 30 are then turned from the unlocking state into the locking state, whereby the barbs 342 are expanded and held beneath the printed circuit board 50 to lock the heat dissipation device securely onto the heat-generating component 52.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device, comprising:
a heat sink having a central core, a plurality of branches at a circumference of the core and a plurality of fins extending outwardly from the core and branches, each of the branches having a locking part at a distal end thereof;
a plurality of mounting brackets each comprising a mounting plate engaging with the locking part, a supporting part extending outwardly from a top end of the mounting part and a fixing part extending outwardly from a bottom end of the mounting plate; and
a fan supported and secured on the supporting part.

2. The heat dissipation device as described in claim 1, wherein each of the locking parts comprises a vertical plate and two runners at two opposite lateral sides thereof.

3. The heat dissipation device as described in claim 2, wherein two runners face each other, receive the mounting plate therein and are formed by two flanges extending perpendicularly and outwardly from two opposite lateral edges of the vertical plate and then being bent perpendicularly toward each other.

4. The heat dissipation device as described in claim 3, wherein each of the branches is perpendicular to the corresponding vertical plate and connected to a middle portion of an inner side of the vertical plate.

5. The heat dissipation device as described in claim 4, wherein every two neighboring branches are perpendicular to each other.

6. The heat dissipation device as described in claim 1, wherein each of the supporting parts is perpendicular to the mounting plate and therein defines an engaging hole engaging with a screw piercing through the fan.

7. The heat dissipation device as described in claim 6, wherein the supporting part has a width identical to that of the mounting plate and is held on a top of the locking part of the heat sink.

8. The heat dissipation device as described in claim 1, wherein the fixing part is perpendicular to the mounting plate and defines therein a through hole receiving a fixture.

9. The heat dissipation device as described in claim 8, wherein a joint between the mounting plate and the fixing plate recess inwardly from two opposite lateral sides, therefore has a width less than that of other parts of the mounting plate to enable two opposite lateral sides of the mounting plate to insert into the locking part.

10. The heat dissipation device as described in claim 1, wherein the branches extend radially from the circumference of the core and are symmetrical to each other.

11. The heat dissipation device as described in claim 10, wherein the core is a solid prism, the fins project outwardly from circumference of the core and lateral sides of the branches.

12. The heat dissipation device as described in claim 11, wherein four portions of the circumference of the core and four pair of the facing lateral sides of the branches form four regions, the fins in the four regions are oriented at four different directions.

13. The heat dissipation device as described in claim 12, wherein two groups of the fins in two neighboring regions are oriented perpendicularly to each other.

14. A heat dissipation device, comprising:
a heat sink having a central core, a plurality of branches at a circumference of the core and a plurality of fins extending outwardly from the core and branches, each of the branches having a locking part at distal end thereof, the locking part comprising a vertical plate and two runners at two opposite lateral sides thereof;
a plurality of mounting brackets each comprising a mounting plate engaging with the locking part, a supporting part extending outwardly from a top end of the mounting part and a fixing part extending outwardly from a bottom end of the mounting plate; and
a fan supported and secured on the supporting part and secured by screws extending therethrough to screw into the supporting plates of the mounting brackets;
wherein the mounting plate of the bracket abut against the vertical plate of the locking part and inserted into the runners of the locking parts.

15. The heat dissipation device as described in claim 14, wherein two runners of each locking part face each other and is formed by two flanges extending perpendicularly and outwardly from two opposite lateral edges of the vertical plate and then being bent perpendicularly toward each other.

16. The heat dissipation device as described in claim 14, wherein the supporting part and the fixing part of each of the mounting brackets are parallel to each other.

17. A heat dissipation device for dissipating heat from an electronic component mounted on a printed circuit board, comprising:
a heat sink comprising a plurality of fins, a plurality of sliding channels defined at corners of the heat sink;
a plurality of mounting brackets each comprising a mounting plate slidably received in a corresponding channel, a supporting plate perpendicularly extending from a top of the mounting plate and located at a top of the heat sink to support a fan thereon, and a fixing plate perpendicularly extending from a bottom of the mounting plate; and
a plurality of fasteners extending through the fixing plates of the mounting brackets to mount the heat sink onto the printed circuit board.

18. The heat dissipation device as described in claim 17, wherein the heat sink further comprises a central core and a plurality of branches symmetrically extending from an circumference of the core, the fins extending outwardly from the core and the braches.

19. The heat dissipation device as described in claim 18, wherein a baffle plate extends from an end of each branch, and a pair of flanges are bent from two opposite edges thereof to form the sliding channel.
